(19) United States
(12) Patent Application Publication
(10) Pub. No.: US 2007/0045823 A1
(43) Pub. Date: Mar. 1, 2007

(54) THERMALLY CONDUCTIVE THERMOPLASTICS FOR DIE-LEVEL PACKAGING OF MICROELECTRONICS

(75) Inventor: James D. Miller, Marietta, GA (US)

Correspondence Address: BARLOW, JOSEPHS & HOLMES, LTD., 101 DYER STREET, 5TH FLOOR, PROVIDENCE, RI, 02903, US

(73) Assignee: COOL OPTIONS, INC., Warwick, RI (US)

(21) Appl. No.: 11/467,282

(22) Filed: Aug. 25, 2006

Related U.S. Application Data
(60) Provisional application No. 60/711,583, filed on Aug. 26, 2005.

(51) Int. Cl. H01L 23/34

(52) U.S. Cl. 257/706

(57) ABSTRACT

A composition and method for die-level packaging of microelectronics is disclosed. The composition includes about 20% to about 80% of a thermoplastic base matrix; about 20% to about 70% of a non-metallic, thermally conductive material such that the composition has a coefficient of thermal expansion of less than 20 ppm/C and a thermal conductivity of greater than 1.0 W/mK. Using injection molding techniques, the composition can be molten and then injected into a die containing the microelectronics to encapsulate the microelectronics therein.

### CROSS-REFERENCE TO RELATED APPLICATION

This application claims priority to earlier filed U.S. Provisional Application Ser. No. 60/711,583, filed Aug. 26, 2005, the contents of which are incorporated herein by reference.

### BACKGROUND OF THE INVENTION

1. Field of the Invention

The present invention relates generally to materials for packaging microelectronic components and more specifically to a thermally conductive plastic for packaging such components.

2. Background of the Related Art

In the manufacture of microelectronics products, such as a light emitting diode (“LED”), it is desirable to manufacture a component that has small dimensions for a number of reasons including the general trend in miniaturization of electronics to the aesthetic appeal of certain smaller form factors. However because of the smaller dimensions of the packaging, the heat dissipation characteristics of the component are degraded which may lead to the degradation of the component's performance, erratic behavior, a shortened lifespan, and other undesirable consequences. All of these problems are well documented in the art. Therefore, there is a need for a material that has high thermal conductivity that is suitable for use in packaging microelectronics.

Moreover, regarding LEDs in particular, the trend in the industry has been to increase the brightness of LEDs. The increase in brightness has been accomplished in part by increasing the power consumed by the LED. Increasing the power applied to the LED has caused an increase in the operating temperature of the LED, thus requiring new methods of thermal management for LEDs. Therefore, there is a need for a material with high thermal conductivity that can be used in the packaging of LEDs.

Generally speaking, it is a well known concept in physics and chemistry that materials expand as the surrounding temperature increases. Different materials expand at different rates according to the physical properties of the material in question. When two different materials with different thermal expansion rates are placed in close proximity to one another, the material with the higher rate of expansion will tend to push the material with the lower expansion rate. In some applications, this known property can be very useful. In the packaging of microelectronics, however, this thermal expansion property presents a hurdle to be overcome because if the thermal expansion properties of adjacent materials are not closely matched to one another, a microelectronic device may fail under operating temperatures due to the materials separating apart. Therefore, there is a need for a thermally conductive material for encapsulating microelectronic devices that has a thermal expansion rate similar to that of the fragile encapsulated circuitry.

### SUMMARY OF THE INVENTION

The present invention solves the problems of the prior art by providing a thermally conductive thermoplastic that can be used as an encapsulant for packaging microelectronic devices. The preferred material of the invention of the present application is based on modified grades of high temperature thermoplastics including LCP, PPS, PEEK, polyimide, certain polyamides, and other thermoplastics that can withstand the high temperature (lead free) reflow temperatures required for most higher-power LEDs. The preferred material to act as this additive is hexagonal boron nitride. The loading levels of hBN that are typical to achieve the required properties are typically 20 to 70 weight percent, but more preferably 30 to 65 weight percent.

The composition can then be molten and injected into a die containing microelectronics using injection molding techniques to encapsulate the microelectronics within the composition.

Accordingly, among the objects of the present invention is the provision for a composition for encapsulating microelectronics that has low thermal expansion properties.

Another object of the present invention is the provision for a composition for encapsulating microelectronics that is thermally conductive.

### BRIEF DESCRIPTION OF THE DRAWINGS

These and other features, aspects, and advantages of the present invention will become better understood with reference to the following description, appended claims, and accompanying drawings where:

FIG. 1 is a perspective view of an exemplary LED encapsulated in the composition of the present invention; and

FIG. 2 is a top view of the encapsulated LED shown in FIG. 1.

### DETAILED DESCRIPTION OF THE INVENTION

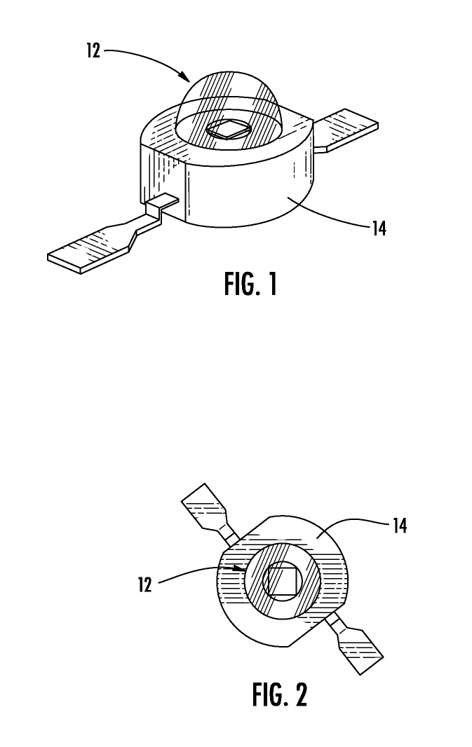

Referring to FIGS. 1 and 2, the present invention solves the problems of the prior art by providing a thermally conductive thermoplastic that can be used as an encapsulant for packaging microelectronic devices, such as LEDs. A microelectronic device 12, such as the LED depicted in FIGS. 1 and 2, maybe be encapsulated by the thermally conductive thermoplastic 14 using injection molding techniques known in the art.

The preferred material of the invention of the present application is based on modified grades of high temperature thermoplastics including LCP, PPS, PEEK, polyimide, certain polyamides, and other thermoplastics that can withstand the high temperature (lead free) reflow temperatures required for most higher-power LEDs. LCP and PPS are preferred embodiments as they offer a balance of processability and high temperature performance. These materials also have the added advantage of being capable of being used in injection molding processes. The thermally conductive and controlled expansion molding resin is fabricated by compounding the high temperature thermoplastic with additives that have inherent high thermal conductivity, are electrical insulators, have low or negative coefficient of thermal expansion, have lower hardness than steel, and have reasonably isotropic properties in at least two directions. The preferred material to act as this additive is hexagonal boron nitride. Other materials can be added and may meet some of many of the requirements listed. Only hexagonal boron nitride meets all the requirements. Many other additives can be included in the polymer compound to ensure a range of processing and performance requirements.

The desirable thermal conductivity of the invention based on the power and conduction path length in LED packaging designs is greater than 1.0 W/mK and preferably greater than 1.5 W/mK and more preferably greater than 2.0 W/mK. The desirable coefficient of thermal expansion of the invention based on the thermal expansion of other components is less than 20 ppm/C, preferably less than 15 ppm/C and more preferably less than 10 ppm/C.

To achieve the invention properties it is required that the hBN have specific properties (e.g. oxygen content, crystal size, purity) and be compounded efficiently to translate its properties. Specifically, oxygen content of less than 0.6% and impurities of less than 0.06% B₂O₃ is especially desirable. The particles of hBN are preferably in flake form and range between D50, microns of 10<50 and having a surface area of between about 0.3 to 5 m²/g. The tap density of the hBN is also preferably greater than 0.5 g/cc. The loading levels that are typical to achieve the required properties are typically 20 to 70 weight percent, but more preferably 30 to 65 weight percent. Outside of these specific property ranges, the composition begins to exhibit undesirable thermal expansion characterisitcs.

The electrical insulation property of the composition is preferably 10E12 ohm-cm electrical resistivity or higher. More preferably the electrical resistivity is 10E14 ohm-cm or higher and even more preferably 10E16 ohm-cm. Because the composition of the present invention is being used as an encapsulant for a microelectrical device, the composition must be a good electrical insulator to function properly.

Other electrical properties are also important. For instance, a dielectric constant of 5.0 or less is desirable, but preferably 4.0 or less and even more preferably 3.5 or less. Dielectric strength is also an important characteristic of the composition. A dielectric strength greater than 400 V/mil is desirable, greater than 600 V/mil is prefered and greater than 700 V/mil is even more preferred. Dielectric loss or dissipation factor is also important. A dielectric loss of less than 0.1 is desirable, less than 0.01 is preferred and less than 0.001 more is most preferred.

Comparative tracking index, arc resistance, hot wire ignition, high voltage arc tracking resistance, and high voltage arc resistance to ignition characteristics are also all important and typically improved in the thermally conductive plastic base matrix compared to conventional plastics. Some of these tests are industry specific or industry common (e.g. UL for electrical industry, automotive, etc).

An optional reinforcing material can be added to the polymer matrix. The reinforcing material can be glass fiber, inorganic minerals, or other suitable material. The reinforcing material strengthens the polymer matrix. The reinforcing material, if added, constitutes about 3% to about 25% by weight of the composition, but more preferably between about 10% and about 15%.

The thermally-conductive material and optional reinforcing material are intimately mixed with the non-conductive polymer matrix to form the polymer composition. If desired, the mixture may contain additives such as, for example, flame retardants, antioxidants, plasticizers, dispersing aids, and mold-releasing agents. Preferably, such additives are biologically inert. The mixture can be prepared using techniques known in the art.

The present invention is further illustrated by the following examples, but these examples should not be construed as limiting the invention.

### EXAMPLE 1

In this example, a composition containing a thermoplastic base matrix of about about 35% PPS was highly loaded with about 65% hBN. The example exhibited a thermal conductivity of 10 W/mK and had a thermal coefficient of expansion of 6 ppm/C. This example also exhibited an electrical resistivity of 2.5E16 ohm-cm. This example also had good mechanical strength, resisting tensile forces of 36 MPa, flexural forces of 68 Mpa, and impacts ranging from 1-3 kJ/m², respectively.

### EXAMPLE 2

In this example, a composition containing a thermoplastic base matrix of about about 40% LCP was highly loaded with about 60% hBN. The example exhibited a thermal conductivity of 10 W/mK and had a thermal coefficient of expansion of 11.3 ppm/C. This example also exhibited an electrical resistivity of 1.6E16 ohm-cm. This example also had good mechanical strength, resisting tensile forces of 55 MPa, flexural forces of 84 MPa, and impacts ranging from 2.8-5.6 kJ/m², respectively.

Therefore, it can be seen that the present invention provides a unique solution by providing a thermoplastic that can be used as an ecapsulant with has high thermal conductivity and low thermal expansion properties which is suitable for packaging a microelectronic device.

It would be appreciated by those skilled in the art that various changes and modifications can be made to the illustrated embodiments without departing from the spirit of the present invention. All such modifications and changes are intended to be within the scope of the present invention, except insofar as limited by the appended claims.

What is claimed:

1. A composition for die-level packaging of microelectronics, comprising:
about 20% to about 80% of a thermoplastic base polymer matrix;
about 20% to about 70% of a non-metallic, thermally conductive material;
said composition having a coefficient of thermal expansion of less than 20 ppm/C and a thermal conductivity of greater than 1.0 W/mK.

2. The composition of claim 1, wherein said composition comprises about 30% to about 65% the non-metallic, thermally conductive material.

3. The composition of claim 1, wherein said non-metallic, thermally conductive material is hexagonal Boron Nitride.

4. The composition of claim 3, wherein said hexagonal Boron Nitride has grain sizes of D50, microns from about 10 to about 50.

5. The composition of claim 3, wherein said hexagonal Boron Nitride has less than 0.6% O₂.

6. The composition of claim 3, wherein said hexagonal Boron Nitride has less than 0.06% B₂O₃.

7. The composition of claim 3, wherein said hexagonal Boron Nitride has a surface area between about 0.3 to about 5 m²/g.

8. The composition of claim 1, wherein said thermoplastic base polymer matrix is selected from the group consisting essentially of: LCP, PPS, PEEK, polyimide, and polyamides.

9. The composition of claim 1, wherein the composition has a coefficient of thermal expansion of less than 15 ppm/C.

10. The composition of claim 1, wherein the composition has a coefficient of thermal expansion of less than 10 ppm/C.

11. The composition of claim 1, wherein the composition has a thermal conductivity of greater than 1.5 W/mK.

12. The composition of claim 1, wherein the composition has a thermal conductivity of greater than 2.0 W/mK.

13. The composition of claim 1, further comprising about 3 to about 25 percent of a reinforcing material.

14. The composition of claim 13, wherein said reinforcing material comprises glass fiber.

15. A method of die-level packaging of microelectronics, comprising the steps of:
a) providing a molten composition comprising: i) about 20% to about 80% by weight of a thermoplastic base polymer matrix, and ii) about 20% to about 70% by weight of a non-metallic, thermally-conductive material; said composition having a coefficient of thermal expansion of less than 20 ppm/C and a thermal conductivity of greater than 1.0 W/mK.
b) providing microelectronics desired to be encapsulated by said molten composition, said microelectronics being held securely within a die;
c) injecting the molten composition into said die; and
d) removing the microelectronics from said die.

16. The method of claim 15, wherein said composition comprises about 30% to about 65% the non-metallic, thermally conductive material.

17. The method of claim 15, wherein said non-metallic, thermally conductive material is hexagonal Boron Nitride.

18. The composition of claim 17, wherein said hexagonal Boron Nitride has grain sizes of D50, microns from about 10 to about 50.

19. The composition of claim 17, wherein said hexagonal Boron Nitride has less than 0.6% O₂.

20. The composition of claim 17, wherein said hexagonal Boron Nitride has less than 0.06% B₂O₃.

21. The composition of claim 17, wherein said hexagonal Boron Nitride has a surface area between about 0.3 to about 5 m²/g.

22. The method of claim 15, wherein said thermoplastic base polymer matrix is selected from the group consisting essentially of: LCP, PPS, PEEK, polyimide, and polyamides.

23. The method of claim 15, wherein the composition has a coefficient of thermal expansion of less than 15 ppm/C.

24. The method of claim 15, wherein the composition has a coefficient of thermal expansion of less than 10 ppm/C.

25. The method of claim 15, wherein the composition has a thermal conductivity of greater than 1.5 W/mK.

26. The method of claim 15, wherein the composition has a thermal conductivity of greater than 2.0 W/mK.

27. The method of claim 15, further comprising adding about 3 to about 25 percent of a reinforcing material to said molten composition.

28. The method of claim 27, wherein said reinforcing material comprises glass fiber.
